(19) United States
(12) Patent Application Publication
(10) Pub. No.: US 2024/0429085 A1
(43) Pub. Date: Dec. 26, 2024

(54) RETENTION DEVICE, AND ELECTROSTATIC CHUCK

(71) Applicant: Niterra Co., Ltd., Nagoya-shi (JP)

(72) Inventors: Akira INAYOSHI, Nagoya-shi (JP); Hideki UEMATSU, Nagoya-shi (JP)

(21) Appl. No.: 18/746,478

(22) Filed: Jun. 18, 2024

(30) Foreign Application Priority Data
Jun. 22, 2023 (JP) 2023-102267

(51) Int. Cl. H01L 21/683

(52) U.S. Cl. CPC H01L 21/6833

(57) ABSTRACT

A retention device includes one of (A) to (C). (A): Fillers in a joining layer are in contact with a retention member or a base member. (B): First and second ratios are areas of fillers in first and second ranges of 1 μm or less from interfaces with the retention member and the base member to areas of the first and second ranges, respectively, and a third ratio is an area of fillers in a third range of 30% or less in a thickness direction on either side of a center of the joining layer to the area of the third range, and dividing the first or second ratio by the third ratio is 0.5 or greater. (C): A number of the fillers having an aspect ratio of 1.4 or greater is larger than a number of the fillers having an aspect ratio of less than 1.4.

### TECHNICAL FIELD

The present invention relates to a retention device and an electrostatic chuck.

### BACKGROUND ART

Retention members that retain a target object by electrostatic attraction are known. For example, Patent Document 1 discloses an electrostatic chuck including such a retention member, a base member, and a joining layer joining the retention member and the base member. The joining layer includes a first resin layer containing a filler, and a second resin layer not containing a filler, and the second resin layer is placed between the first resin layer and the retention member and between the first resin layer and the base member.

### PRIOR ART DOCUMENT

### Patent Document

Patent Document 1: Japanese Patent No. 6321522

### SUMMARY OF THE INVENTION

### Problem to be Solved by the Invention

In the electrostatic chuck described in Patent Document 1, the second resin layer, which has lower thermal conductivity than the first resin layer by containing no filler, exists at the interface of the joining layer with the retention member and the interface of the joining layer with the base member, thereby increasing the thermal resistance of the joining layer. Therefore, there is room for improvement in reducing the thermal resistance of the joining layer.

The present invention has been made to solve at least a part of the above problems, and an object of the present invention is to provide a technology capable of reducing the thermal resistance of a joining layer.

### Means for Solving the Problem

The present invention has been made to solve at least a part of the above problems and can be implemented as the following aspects.

(1) One aspect of the present invention provides a retention device. This retention device includes: a retention member having a retention surface for retaining a target object; a base member placed on a side of the retention member opposite to the retention surface side; and a joining layer joining the retention member and the base member and containing a plurality of fillers, and satisfies at least one of the following conditions (A) to (C).

Condition (A): The fillers include at least either first fillers in contact with the retention member or second fillers in contact with the base member.

Condition (B): When a ratio of a sum of cross-sectional areas of the fillers in a range of 1 μm or less from an interface of the joining layer with the retention member is defined as a first ratio, a ratio of a sum of cross-sectional areas of the fillers in a range of 1 μm or less from an interface of the joining layer with the base member is defined as a second ratio, and a ratio of a sum of cross-sectional areas of the fillers in a range of 30% or less of a thickness of the joining layer from a center of the joining layer in a thickness direction of the joining layer to the retention member side and a range of 30% or less of the thickness of the joining layer from the center to the base member side is defined as a third ratio, at least one of a value obtained by dividing the first ratio by the third ratio and a value obtained by dividing the second ratio by the third ratio is 0.5 or greater.

Condition (C): Among the fillers, a number of the fillers having an aspect ratio of 1.4 or greater is larger than a number of the fillers having an aspect ratio of less than 1.4.

According to this configuration, the retention device satisfies at least one of the conditions (A) to (C). When the condition (A) is satisfied, since the fillers having relatively high thermal conductivity are in contact with at least one of the retention member and the base member, the thermal resistance at at least one of the interface between the joining layer and the retention member and the interface between the joining layer and the base member can be reduced. When the condition (B) is satisfied, since a relatively large number of the fillers are contained in at least one of the range of 1 μm or less from the interface of the joining layer with the retention member and the range of 1 μm or less from the interface of the joining layer with the base member, the thermal resistance in at least one of the vicinity of the interface of the joining layer with the retention member and the vicinity of the interface of the joining layer with the base member can be reduced. When the condition (C) is satisfied, since the number of fillers having an aspect ratio of 1.4 or greater is larger than the number of fillers having an aspect ratio of less than 1.4 among the fillers contained in the joining layer, heat can be easily transferred in the thickness direction of the joining layer by fewer fillers, so that the thermal resistance of the joining layer can be reduced while the flexibility of the joining layer is maintained. As described above, the thermal resistance of the joining layer can be reduced by satisfying at least one of the conditions (A) to (C).

(2) In the retention device of the above aspect, the retention device may satisfy at least the condition (A), and at least either the first fillers or the second fillers contained in the joining layer may include large-diameter fillers having a grain size larger than an average grain size of the fillers.

According to this configuration, since at least either the first fillers or the second fillers contained in the joining layer include the large-diameter fillers, heat can be easily transferred in the thickness direction of the joining layer from the interface. As a result, the thermal resistance at the interface can be further reduced.

(3) In the retention device of the above aspect, the retention device may satisfy at least the condition (A), and at least either the first fillers or the second fillers contained in the joining layer may include small-diameter fillers having a grain size smaller than the average grain size.

According to this configuration, since at least either the first fillers or the second fillers contained in the joining layer also include the small-diameter fillers in addition to the large-diameter fillers, the number of fillers in contact with the retention member or the base member is large, so that heat can be more easily transferred in the thickness direction of the joining layer from the interface.

(4) In the retention device of the above aspect, the retention device may satisfy at least the condition (A), and as for at least either the first fillers or the second fillers contained in the joining layer, a sum of cross-sectional areas of the large-diameter fillers may be larger than a sum of cross-sectional areas of the small-diameter fillers.

According to this configuration, as for at least either the first fillers or the second fillers contained in the joining layer, the amount of the large-diameter fillers relative to the amount of the small-diameter fillers is guaranteed to some extent, so that the effect of reducing the thermal resistance at the interface by the large-diameter fillers can be guaranteed.

(5) In the retention device of the above aspect, the retention device may satisfy at least the condition (A), and at least either the first fillers or the second fillers contained in the joining layer may include the fillers having an aspect ratio of 1.4 or greater.

According to this configuration, since at least either the first fillers or the second fillers contained in the joining layer include the fillers having an aspect ratio of 1.4 or greater, heat can be easily transferred in the thickness direction of the joining layer from the interface. As a result, the thermal resistance at the interface can be further reduced.

(6) In the retention device of the above aspect, the retention device may satisfy at least the condition (A), and at least either the first fillers or the second fillers contained in the joining layer may include the fillers having an aspect ratio of less than 1.4.

According to this configuration, since at least either the first fillers or the second fillers contained in the joining layer also include the fillers having an aspect ratio of less than 1.4 in addition to the fillers having an aspect ratio of 1.4 or greater, the number of fillers in contact with the retention member or the base member is large, so that heat can be more easily transferred in the thickness direction of the joining layer from the interface.

(7) In the retention device of the above aspect, the retention device may satisfy at least the condition (A), and as for at least either the first fillers or the second fillers contained in the joining layer, a sum of cross-sectional areas of the fillers having an aspect ratio of 1.4 or greater may be larger than a sum of cross-sectional areas of the fillers having an aspect ratio of less than 1.4.

According to this configuration, as for at least either the first fillers or the second fillers contained in the joining layer, the amount of the fillers having an aspect ratio of 1.4 or greater relative to the amount of the fillers having an aspect ratio of less than 1.4 is guaranteed to some extent, so that reduction of the thermal resistance at the interface by the fillers having an aspect ratio of 1.4 or greater can be guaranteed.

(8) In the retention device of the above aspect, the retention device may satisfy at least the condition (A); on at least either a portion of the retention member that is joined to the joining layer or a portion of the base member that is joined to the joining layer, recesses may be formed so as to be recessed deeper than the average grain size; depths of the recesses may be larger than the average grain size of the fillers, and the recesses may be filled with the joining layer; and large-diameter fillers having a grain size larger than the average grain size of the fillers may be in contact with surfaces defining the recesses.

According to this configuration, the formation of the recesses leads to an increase in surface area, so that the thermal resistance at at least one of the interface of the retention member with the joining layer and the interface of the base member with the joining layer can be reduced. In addition, since the large-diameter fillers having a grain size larger than the average grain size of the fillers are in contact with the surfaces defining the recesses, the thermal resistance at the interface can be further reduced.

(9) In the retention device of the above aspect, the retention device may satisfy at least the condition (A); on at least either a portion of the retention member that is joined to the joining layer or a portion of the base member that is joined to the joining layer, recesses may be formed so as to be recessed deeper than the average grain size; depths of the recesses may be larger than the average grain size of the fillers, and the recesses may be filled with the joining layer; and the fillers having an aspect ratio of 1.4 or greater may be in contact with surfaces defining the recesses.

According to this configuration, the formation of the recesses leads to an increase in surface area, so that the thermal resistance at at least one of the interface of the retention member with the joining layer and the interface of the base member with the joining layer can be reduced. In addition, since the fillers having an aspect ratio of 1.4 or greater are in contact with the surfaces defining the recesses, the thermal resistance at the interface can be further reduced.

(10) Another aspect of the present invention provides an electrostatic chuck. This electrostatic chuck includes: the retention device in accordance with any one of claims 1 to 9; and an electrostatic electrode configured to generate electrostatic attraction on the retention surface.

According to this configuration, electrostatic attraction (attracting force) is generated by supplying electric power to the electrostatic electrode, and a target object can be retained on the retention surface side by this electrostatic attraction. In addition, since the retention device which satisfies at least one of the conditions (A) to (C) is included, it is possible to provide an electrostatic chuck in which the thermal resistance of the joining layer is reduced.

The present invention can be implemented in various aspects. For example, the present invention can be implemented in aspects such as a retention member, an electrostatic chuck including a retention member and an electrostatic electrode configured to generate electrostatic attraction on a retention surface of the retention member, a vacuum chuck, a ceramic heater, a semiconductor manufacturing apparatus, a part including the above-described one(s), and manufacturing methods therefor.

### BRIEF DESCRIPTION OF THE DRAWINGS

FIG. 1 Explanatory diagram schematically showing a cross-sectional configuration of an electrostatic chuck of a first embodiment.

FIG. 2 Enlarged view of a cross-sectional configuration of a joining layer.

FIG. 3 Explanatory diagram in which a portion of each filler is hatched.

FIG. 4 Explanatory diagram showing each range in the cross-sectional configuration of the joining layer.

FIG. 5 Enlarged view of a cross-sectional configuration of a retention device of a second embodiment.

### MODES FOR CARRYING OUT THE INVENTION

### First Embodiment

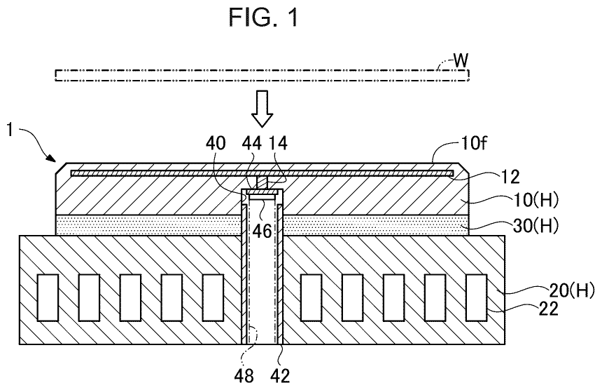

FIG. 1 is an explanatory diagram schematically showing a cross-sectional configuration of an electrostatic chuck 1 of a first embodiment. The electrostatic chuck 1 is a device that attracts and retains a semiconductor wafer W, which is a target object, by electrostatic attraction. An arrow shown in FIG. 1 indicates the direction in which the semiconductor wafer W is attracted to the electrostatic chuck 1. The electrostatic chuck 1 is used, for example, to fix the semiconductor wafer W in a vacuum chamber of a semiconductor manufacturing apparatus. The electrostatic chuck 1 includes a retention member 10, a base member 20, and a joining layer 30. Among the components of the electrostatic chuck 1, the retention member 10, the base member 20, and the joining layer 30 are also collectively referred to as retention device H.

The retention member 10 is a disk-shaped member that retains the semiconductor wafer W, which is a target object, and is formed of alumina, aluminum nitride, or the like. The retention member 10 has a retention surface 10f. The retention surface 10f is a circular surface on the side on which the semiconductor wafer W is retained.

An electrostatic electrode 12 is placed inside the retention member 10. The electrostatic electrode 12 is a disk-shaped member and is formed of a conductive material such as tungsten or molybdenum. A via 14 is connected to the electrostatic electrode 12 inside the retention member 10. The via 14 is a rod-shaped member and is formed of the same material as the electrostatic electrode 12.

The base member 20 is a disk-shaped member placed on the side of the retention member 10 opposite to the retention surface 10f side, and is formed of aluminum, an aluminum alloy, or the like. A refrigerant flow path 22 is placed inside the base member 20. The refrigerant flow path 22 is a flow path through which a cooling medium (e.g., fluorinated liquid, pure water, etc.) is caused to flow.

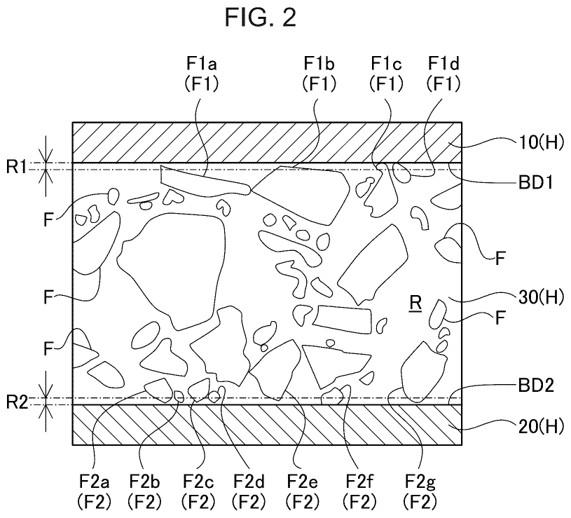

The joining layer 30 is a resin layer R (shown in FIG. 2 and the subsequent drawings) disposed between the retention member 10 and the base member 20 and joining the retention member 10 and the base member 20, and contains a plurality of fillers F (shown in FIG. 2 and the subsequent drawings). The details will be described later.

A through hole 40 is formed inside the electrostatic chuck 1 so as to penetrate the base member 20 and the joining layer 30 to the inside of the retention member 10. A tubular insulating member 42 is fitted into the through hole 40. A metallization layer 44 connected to the via 14 is placed on the bottom surface of the through hole 40 that is located inside the retention member 10. The metallization layer 44 is a plate-shaped member and is formed of the same material as the electrostatic electrode 12 and the via 14. A connection terminal 46 is connected to the metallization layer 44 and to a metal terminal 48. An external power supply, which is not shown, is connected to the metal terminal 48. That is, the electrostatic electrode 12 generates electrostatic attraction on the retention surface 10f by being supplied with electric power from the external power supply, which is not shown, via the via 14, the metallization layer 44, the connection terminal 46, and the metal terminal 48. The semiconductor wafer W is retained on the retention surface 10f by being attracted toward the retention surface 10f by this electrostatic attraction.

FIG. 2 is an enlarged view of a cross-sectional configuration of the joining layer 30. As described above, the joining layer 30 is the resin layer R containing the plurality of fillers F. In FIG. 2, the portions of the joining layer 30 other than the fillers F show the resin layer R. The fillers F have higher thermal conductivity than the resin layer R. The retention device H (retention member 10, base member 20, and joining layer 30) satisfies the following condition (A).

Condition (A): The plurality of fillers F include at least either first fillers F1 in contact with the retention member 10 or second fillers F2 in contact with the base member 20. When images of portions of the joining layer 30 are taken by a scanning electron microscope (SEM), the joining layer 30 is determined to satisfy the condition (A) if the condition (A) can be satisfied at even one of these portions.

As for the condition (A), in the present embodiment, the plurality of fillers F contained in the joining layer 30 include both the first fillers F1 in contact with the retention member 10 and the second fillers F2 in contact with the base member 20. Here, when a filler F is included even partially in a range R1 of 0.5 μm or less from an interface BD1 between the retention member 10 and the joining layer 30 or in a range R2 of 0.5 μm or less from an interface BD2 between the base member 20 and the joining layer 30, such a filler F is defined as a first filler F1 or a second filler F2.

The first fillers F1 include first fillers F1a, F1b, and F1c which are large-diameter fillers having a grain size larger than the average grain size of the fillers F. The second fillers F2 also include second fillers F2a, F2c, F2e, and F2g which are large-diameter fillers having a grain size larger than the average grain size of the fillers F. Furthermore, in the present embodiment, the first fillers F1 and the second fillers F2 each include a first filler F1d or second fillers F2b, F2d, and F2f which are small-diameter fillers having a grain size smaller than the average grain size of the fillers F. Here, the average grain size corresponds to the median size of grain sizes obtained when a cross-sectional image of the joining layer 30 taken by an SEM is binarized, the area of each filler F is approximated to a perfect circle (πr²), and the diameter (2r) thereof is then regarded as the grain size of each filler F. More specifically, a cross-sectional image of the joining layer 30 taken such that at least 500 or more fillers F are included is used, and the median size of the grain sizes of all the fillers F in the cross-sectional image corresponds to the average grain size.

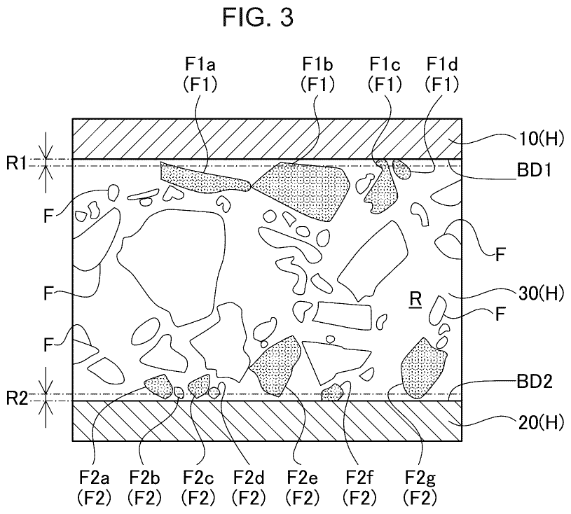

FIG. 3 is an explanatory diagram in which a portion of each of the first fillers F1 and the second fillers F2 shown in FIG. 2 is hatched. Among the first fillers F1, the sum of the cross-sectional areas of the large-diameter fillers is larger than the sum of the cross-sectional areas of the small-diameter fillers. In other words, the sum of the cross-sectional areas of the first fillers F1 having a grain size larger than the average grain size is larger than the sum of the cross-sectional areas of the first fillers F1 having a grain size smaller than the average grain size. Here, when described using FIG. 3, the sum of the cross-sectional areas of the large-diameter fillers among the first fillers F1 (the first fillers F1 having a grain size larger than the average grain size) is not the sum of the cross-sectional areas of the portions, included in the range R1, of the first fillers F1a, F1b, and F1c, but the sum of the cross-sectional areas of the entireties of the first fillers F1a, F1b, and F1c (shown by hatching in the first fillers F1a, F1b, and F1c in FIG. 3). Similarly, when described using FIG. 3, the sum of the cross-sectional areas of the small-diameter fillers among the first fillers F1 (the first fillers F1 having a grain size smaller than the average grain size) is not the sum of the cross-sectional area of the portion, included in the range R1, of the first filler F1d, but the cross-sectional area of the entirety of the first filler F1d (shown by hatching in the first filler F1d in FIG. 3).

As with the first fillers F1, among the second fillers F2, the sum of the cross-sectional areas of the large-diameter fillers is larger than the sum of the cross-sectional areas of the small-diameter fillers. When described using FIG. 3, the sum of the cross-sectional areas of the entireties of the second fillers F2a, F2c, F2e, and F2g (shown by hatching in the second fillers F2a, F2c, F2e, and F2g in FIG. 3) is larger than the sum of the cross-sectional areas of the entireties of the second fillers F2b, F2d, and F2f (shown by hatching in the second fillers F2b, F2d, and F2f in FIG. 3).

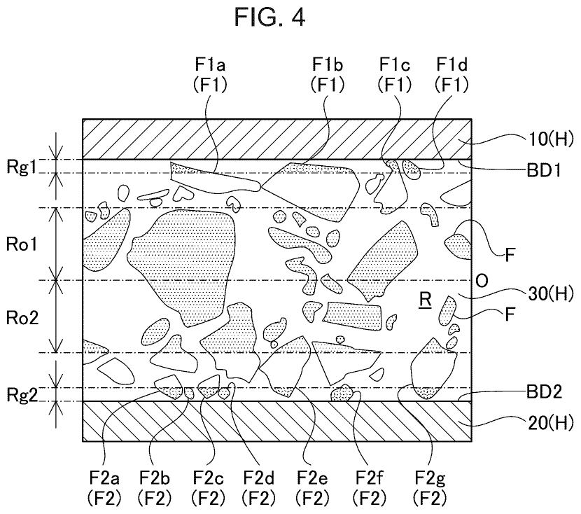

In addition to the above condition (A), the retention device H also satisfies the following condition (B). A range Rg1, a range Rg2, a center O, a range Ro1, and a range Ro2 in the following condition (B) are shown in FIG. 4.

Condition (B): When the ratio of the sum of the cross-sectional areas of the fillers F in the range Rg1 of 1 μm or less from the interface BD1 of the joining layer 30 with the retention member 10 is defined as a first ratio, the ratio of the sum of the cross-sectional areas of the fillers F in the range Rg2 of 1 μm or less from the interface BD2 of the joining layer 30 with the base member 20 is defined as a second ratio, and the ratio of the sum of the cross-sectional areas of the fillers F in the range Ro1 of 30% or less of the thickness of the joining layer 30 from the center O of the joining layer 30 in the thickness direction of the joining layer 30 to the retention member 10 side and the range Ro2 of 30% or less of the thickness of the joining layer 30 from the center O to the base member 20 side is defined as a third ratio, at least one of a value obtained by dividing the first ratio by the third ratio and a value obtained by dividing the second ratio by the third ratio is 0.5 or greater.

When images of portions of the joining layer 30 are taken by an SEM, the joining layer 30 is determined to satisfy the condition (B) if the condition (B) can be satisfied at even one of these portions. In this case, the value obtained by dividing the first ratio by the third ratio and the value obtained by dividing the second ratio by the third ratio, which are the criteria for determining whether or not the condition (B) is satisfied, are values calculated using the first to third ratios calculated in the same cross-sectional image.

As for the condition (B), in the present embodiment, both the value obtained by dividing the first ratio by the third ratio and the value obtained by dividing the second ratio by the third ratio are 0.5 or greater. Here, when described using FIG. 4, the ratio of the sum of the cross-sectional areas of the fillers F in the range Rg1 (first ratio) is the ratio of the sum of the cross-sectional areas of the portions of the first fillers Fla to F1d included in the range Rg1 (shown by hatching in the first fillers Fla to F1d in FIG. 4) to the cross-sectional area of the range Rg1. Similarly, when described using FIG. 4, the ratio of the sum of the cross-sectional areas of the fillers F in the range Rg2 is the sum of the areas of the portions of the second fillers F2a to F2g included in the range Rg2 (shown by hatching in the second fillers F2a to F2g in FIG. 4) to the cross-sectional area of the range Rg2.

The ratio of the sum of the cross-sectional areas of the fillers F in the range Ro1 and the range Ro2 (third ratio) is the ratio of the sum of the cross-sectional areas of the portions of the respective fillers F included in the range Ro1 and the range Ro2 (shown by hatching in the fillers F in the range Ro1 and the range Ro2 in FIG. 4) to the sum of the cross-sectional area of the range Ro1 and the cross-sectional area of the range Ro2.

In addition to the above conditions (A) and (B), the retention device H also satisfies the following condition (C). The aspect ratio of each filler F is obtained by binarizing a cross-sectional image of the joining layer 30 taken by an SEM, approximating each filler F to an ellipse by fitting using the least-squares method, and then dividing the major diameter of the ellipse by the minor diameter of the ellipse.

Condition (C): Among the fillers F, the number of fillers F having an aspect ratio of 1.4 or greater is larger than the number of fillers F having an aspect ratio of less than 1.4. When images of portions of the joining layer 30 are taken by an SEM, the joining layer 30 is determined to satisfy the condition (C) if the condition (C) can be satisfied at even one of these portions. More specifically, the joining layer 30 is determined to satisfy the condition (C) if even one cross-sectional image satisfying the condition (C) is confirmed among cross-sectional images of the joining layer 30 taken such that at least 500 or more fillers F are included.

As for the condition (C), in the present embodiment, the first fillers F1 (the fillers F in contact with the retention member 10) and the second fillers F2 (the fillers F in contact with the base member 20) each include fillers F having an aspect ratio of 1.4 or greater. The first fillers F1 and the second fillers F2 each also include fillers F having an aspect ratio of less than 1.4. Among the first fillers F1, the sum of the cross-sectional areas of the fillers F having an aspect ratio of 1.4 or greater is larger than the sum of the cross-sectional areas of the fillers F having an aspect ratio of less than 1.4. Similarly, among the second fillers F2, the sum of the cross-sectional areas of the fillers F having an aspect ratio of 1.4 or greater is larger than the sum of the cross-sectional areas of the fillers F having an aspect ratio of less than 1.4. As in the case of the large-diameter fillers and the small-diameter fillers described above, the sum of the cross-sectional areas here is not the sum of the cross-sectional areas of the portions, included in the range R1 or R2, of the respective fillers F, but the sum of the cross-sectional areas of the entireties of the respective fillers F.

In the electrostatic chuck 1, the retention device H is caused to satisfy the condition (C) by causing a resin material (material on which the joining layer 30 is based) to contain the fillers F such that more fillers F having an aspect ratio of 1.4 or greater are contained than the fillers F having an aspect ratio of less than 1.4. The electrostatic chuck 1 is manufactured by applying such a resin material onto the surface of the base member 20, thermally curing the resin material to form the joining layer 30, and then placing the retention member 10 on the surface of the joining layer 30 on the side opposite to the base member 20 during manufacture. In this manufacturing process, a load is applied to the resin material in the thickness direction in a semi-cured state before the resin material is fully cured to form the joining layer 30, such that the fillers F are easily placed on the end side in the thickness direction of the resin material (joining layer 30) (in the vicinity of the interface with the retention member 10 and in the vicinity of the interface with the base member 20). Then, the resin material becomes the joining layer 30 when the resin material is fully cured with the load applied thereto. By applying the load when the resin material is semi-cured as described above, the large-diameter fillers and the fillers F having an aspect ratio of 1.4 or greater are more likely to be placed on the end side in the thickness direction of the resin material (joining layer 30), in particular. That is, by applying the load when the resin material is semi-cured, the retention device H is more likely to satisfy the conditions (A) and (B).

As described above, the retention device H (retention member 10, base member 20, and joining layer 30) included in the electrostatic chuck 1 of the present embodiment satisfies all of the conditions (A) to (C). When the condition (A) is satisfied, since the first fillers F1 and the second fillers F2 among the fillers F having relatively high thermal conductivity (compared to the resin layer R) are in contact with the retention member 10 and the base member 20, the thermal resistance at both the interface BD1 (see FIGS. 2 to 4) between the joining layer 30 and the retention member 10 and the interface BD2 (see FIGS. 2 to 4) between the joining layer 30 and the base member 20 can be reduced. When the condition (B) is satisfied, since a relatively large amount of the fillers F are included in both the range Rg1 of 1 μm or less from the interface BD1 and the range Rg2 of 1 μm or less from the interface BD2 (first ratio/third ratio=0.5 and second ratio/third ratio=0.5), the thermal resistance both in the vicinity of the interface BD1 and in the vicinity of the interface BD2 can be reduced. When the condition (C) is satisfied, since the number of fillers F having an aspect ratio of 1.4 or greater is larger than the number of fillers F having an aspect ratio of less than 1.4 among the fillers F contained in the joining layer 30, heat can be easily transferred in the thickness direction of the joining layer 30 by fewer fillers F, so that the thermal resistance of the joining layer 30 can be reduced while the flexibility of the joining layer 30 is maintained. Thus, the thermal resistance of the joining layer 30 can be reduced by the retention device H satisfying all of the conditions (A) to (C).

In the retention device H included in the present embodiment, the first fillers F1 and the second fillers F2 include the first fillers F1a, F1b, and F1c and the second fillers F2a, F2c, F2e, and F2g which are large-diameter fillers having a grain size larger than the average grain size of the fillers F. Therefore, heat can be easily transferred in the thickness direction of the joining layer 30 from the interfaces BD1 and BD2. As a result, the thermal resistance at the interfaces BD1 and BD2 can be further reduced.

In the retention device H included in the present embodiment, in addition to the large-diameter fillers, the first fillers F1 and the second fillers F2 include the first filler F1d and the second fillers F2b, F2d, and F2f which are small-diameter fillers having a grain size smaller than the average grain size of the fillers F. Therefore, since the numbers of fillers F in contact with the retention member 10 and the base member 20 are large, heat can be more easily transferred in the thickness direction of the joining layer 30 from the interfaces BD1 and BD2.

In the retention device H included in the present embodiment, as for the first fillers F1, the sum of the cross-sectional areas of the large-diameter fillers (corresponding to F1a, F1b, and F1c in FIG. 2) is larger than the sum of the cross-sectional areas of the small-diameter fillers (corresponding to F1d in FIG. 2). As for the second fillers F2, the sum of the cross-sectional areas of the large-diameter fillers (corresponding to F2a, F2c, F2e, and F2g in FIG. 2) is larger than the sum of the cross-sectional areas of the small-diameter fillers (corresponding to F2b, F2d, and F2f in FIG. 2). Therefore, as for both the first fillers F1 and the second fillers F2, the amount of the large-diameter fillers relative to the amount of the small-diameter fillers is guaranteed to some extent, so that the effect of reducing the thermal resistance at the interfaces BD1 and BD2 by the large-diameter fillers can be guaranteed.

In the retention device H included in the present embodiment, the first fillers F1 and the second fillers F2 include fillers F having an aspect ratio of 1.4 or greater. Therefore, heat can be easily transferred in the thickness direction of the joining layer 30 from the interfaces BD1 and BD2. As a result, the thermal resistance at the interfaces BD1 and BD2 can be further reduced.

In the retention device H included in the present embodiment, in addition to the fillers F having an aspect ratio of 1.4 or greater, the first fillers F1 and the second fillers F2 include fillers F having an aspect ratio of less than 1.4. Therefore, since the numbers of fillers F in contact with the retention member 10 and the base member 20 are large, heat can be more easily transferred in the thickness direction of the joining layer 30 from the interfaces BD1 and BD2.

In the retention device H included in the present embodiment, as for both the first fillers F1 and the second fillers F2, the sum of the cross-sectional areas of the fillers F having an aspect ratio of 1.4 or greater is larger than the sum of the cross-sectional areas of the fillers F having an aspect ratio of less than 1.4. Therefore, as for both the first fillers F1 and the second fillers F2, the amount of the fillers having an aspect ratio of 1.4 or greater relative to the amount of the fillers having an aspect ratio of less than 1.4 is guaranteed to some extent, so that the effect of reducing the thermal resistance at the interfaces BD1 and BD2 by the fillers having an aspect ratio of 1.4 or greater can be guaranteed.

In the electrostatic chuck 1 of the present embodiment, electrostatic attraction (attracting force) is generated by supplying electric power to the electrostatic electrode 12, and the semiconductor wafer W can be retained on the retention surface 10f side by this electrostatic attraction. In addition, since the retention device H which satisfies all of the conditions (A) to (C) is included, it is possible to provide the electrostatic chuck 1 in which the thermal resistance of the joining layer 30 is reduced.

### Second Embodiment

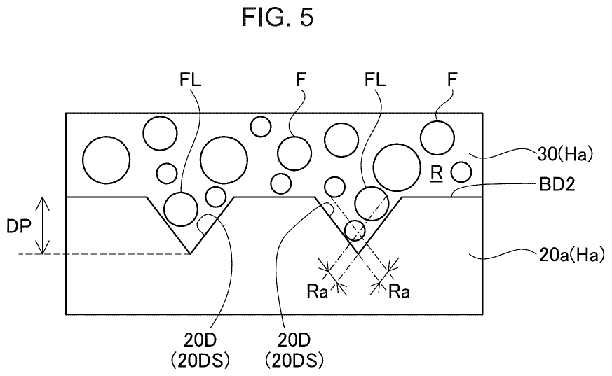

FIG. 5 is an explanatory diagram showing a base member 20a and a joining layer 30 in a retention device Ha of a second embodiment. Compared to the retention device H of the first embodiment, the retention device Ha of the second embodiment is the same as the retention device H of the first embodiment, except that the base member 20a different from the base member 20 is included. That is, similar to the retention device H of the first embodiment, the retention device Ha of the second embodiment is configured to be included in an electrostatic chuck 1. In the description of the second embodiment, the same components as those of the first embodiment are designated by the same reference numerals, and the preceding description is referred to. In FIG. 1 to FIG. 4, the base member 20 is hatched, but in FIG. 5, the base member 20 is not hatched for convenience of illustration. Also, in FIG. 5, fillers F are shown as circles for convenience of illustration.

On a portion of the base member 20a that is joined to the joining layer 30, recesses 20D are formed so as to be recessed deeper than the average grain size of the fillers F. The recesses 20D are formed by laser processing or the like. In addition, a depth DP of each recess 20D is larger than the average grain size of the fillers F, and the recesses 20D are filled with the joining layer 30. Furthermore, large-diameter fillers FL having a grain size larger than the average grain size of the fillers F are in contact with surfaces 20DS defining the recesses 20D. Here, if a filler F is included even partially in a range Ra of 0.5 μm or less from the surface 20DS, such a filler F is considered to be in contact with the surface 20DS. At each recess 20D, the surface 20DS can be considered as the interface BD2, and thus the range Rg2 (see FIG. 4) is specified as a range of 1 μm or less from the surface 20DS.

In the retention device Ha of the second embodiment described above, the thermal resistance of the joining layer 30 can be reduced as in the first embodiment. In the retention device Ha of the second embodiment, the formation of the recesses 20D leads to an increase in surface area, so that the thermal resistance at the interface BD2 of the base member 20a with the joining layer 30 can be reduced. In addition, since the large-diameter fillers FL having a grain size larger than the average grain size of the fillers F are in contact with the surfaces 20DS defining the recesses 20D, the thermal resistance at the interface BD2 can be further reduced.

### Modifications of Embodiments

The present invention is not limited to the above embodiments and may be implemented in various embodiments without deviating from the gist of the present invention. For example, the following modifications are also possible.

In the above embodiments, a plurality of heater electrodes formed of a conductive material such as tungsten or molybdenum may be further provided inside the retention member 10. In such an embodiment, when a target object is retained on the retention member 10, the heater electrodes can generate heat with electric power supplied from an external power supply, thereby warming the target object.

In the above embodiments, the retention devices H and Ha satisfy all of the conditions (A) to (C), but the present invention is not limited thereto. The retention devices H and Ha only need to satisfy at least one of the conditions (A) to (C).

In the above embodiments, the condition (A) is satisfied by including both the first fillers F1 (the fillers F in contact with the retention member 10) and the second fillers F2 (the fillers F in contact with the base member 20) in the plurality of fillers F contained in the joining layer 30, but the present invention is not limited thereto. The condition (A) may be satisfied by including only either the first fillers F1 or the second fillers F2 in the plurality of fillers F contained in the joining layer 30.

In the above embodiments, both the first fillers F1 and the second fillers F2 include large-diameter fillers and small-diameter fillers, but the present invention is not limited thereto. The first fillers F1 and the second fillers F2 may each include only either large-diameter fillers or small-diameter fillers.

In the above embodiments, as for both the first fillers F1 and the second fillers F2, the sum of the cross-sectional areas of the large-diameter fillers is larger than the sum of the cross-sectional areas of the small-diameter fillers, but the present invention is not limited thereto. As for either the first fillers F1 or the second fillers F2, the sum of the cross-sectional areas of the large-diameter fillers may be larger than the sum of the cross-sectional areas of the small-diameter fillers. Alternatively, as for both the first fillers F1 and the second fillers F2, the sum of the cross-sectional areas of the large-diameter fillers may be smaller than the sum of the cross-sectional areas of the small-diameter fillers.

In the above embodiments, the condition (B) is satisfied by both the value obtained by dividing the first ratio by the third ratio and the value obtained by dividing the second ratio by the third ratio being 0.5 or greater, but the present invention is not limited thereto. The condition (B) may be satisfied by only one of the value obtained by dividing the first ratio by the third ratio and the value obtained by dividing the second ratio by the third ratio being 0.5 or greater.

In the above embodiments, both the first fillers F1 and the second fillers F2 include fillers F having an aspect ratio of 1.4 or greater and fillers F having an aspect ratio of less than 1.4, but the present invention is not limited thereto. The first fillers F1 and the second fillers F2 may each include only either fillers F having an aspect ratio of 1.4 or greater or fillers F having an aspect ratio of less than 1.4.

In the above embodiments, as for both the first fillers F1 and the second fillers F2, the sum of the cross-sectional areas of the fillers F having an aspect ratio of 1.4 or greater is larger than the sum of the cross-sectional areas of the fillers F having an aspect ratio of less than 1.4, but the present invention is not limited thereto. As for either the first fillers F1 or the second fillers F2, the sum of the cross-sectional areas of the fillers F having an aspect ratio of 1.4 or greater may be larger than the sum of the cross-sectional areas of the fillers F having an aspect ratio of less than 1.4. Alternatively, as for both the first fillers F1 and the second fillers F2, the sum of the cross-sectional areas of the fillers F having an aspect ratio of 1.4 or greater may be smaller than the sum of the cross-sectional areas of the fillers F having an aspect ratio of less than 1.4.

In the second embodiment, the recesses 20D are formed on the portion of the base member 20a that is joined to the joining layer 30, but the present invention is not limited thereto. Similar recesses may be formed on a portion of the retention member 10 that is joined to the joining layer 30. In such an embodiment, when large-diameter fillers FL having a grain size larger than the average grain size of the fillers F are in contact with surfaces defining these recesses, the thermal resistance at the interface BD1 (see FIG. 2, etc.) can be further reduced. Also, instead of or in addition to the large-diameter fillers FL, fillers F having an aspect ratio of 1.4 or greater may be in contact with the surfaces defining the recesses 20D and the surfaces defining the recesses formed on the retention member 10. In such an embodiment as well, the thermal resistance at the interfaces BD1 and BD2 (see FIG. 2, etc.) can be further reduced.

While the present aspect has been described above using the embodiments and the modifications, the embodiments described above are merely for facilitating the understanding of the present aspect and are not intended to limit the present aspect. The present aspect may be subjected to change or modification without deviating from the gist thereof and the scope of the claims, and the present aspect includes equivalents thereof. Further, such technical features can be deleted as appropriate if not described as being essential in the present specification.

The present invention can be implemented in the following aspects.

### Application Example 1

A retention device including:
a retention member having a retention surface for retaining a target object;
a base member placed on a side of the retention member opposite to the retention surface side; and
a joining layer joining the retention member and the base member and containing a plurality of fillers, wherein the retention device satisfies at least one of the following conditions (A) to (C),
Condition (A): the fillers include at least either first fillers in contact with the retention member or second fillers in contact with the base member,
Condition (B): when a ratio of a sum of cross-sectional areas of the fillers in a range of 1 μm or less from an interface of the joining layer with the retention member is defined as a first ratio, a ratio of a sum of cross-sectional areas of the fillers in a range of 1 μm or less from an interface of the joining layer with the base member is defined as a second ratio, and a ratio of a sum of cross-sectional areas of the fillers in a range of 30% or less of a thickness of the joining layer from a center of the joining layer in a thickness direction of the joining layer to the retention member side and a range of 30% or less of the thickness of the joining layer from the center to the base member side is defined as a third ratio, at least one of a value obtained by dividing the first ratio by the third ratio and a value obtained by dividing the second ratio by the third ratio is 0.5 or greater, and
Condition (C): among the fillers, a number of the fillers having an aspect ratio of 1.4 or greater is larger than a number of the fillers having an aspect ratio of less than 1.4.

### Application Example 2

The retention device in accordance with application example 1, wherein
the retention device satisfies at least the condition (A), and
at least either the first fillers or the second fillers contained in the joining layer include large-diameter fillers having a grain size larger than an average grain size of the fillers.

### Application Example 3

The retention device in accordance with application example 1 or 2, wherein
the retention device satisfies at least the condition (A), and
at least either the first fillers or the second fillers contained in the joining layer include small-diameter fillers having a grain size smaller than the average grain size.

### Application Example 4

The retention device in accordance with any one of application examples 1 to 3, wherein
the retention device satisfies at least the condition (A), and
as for at least either the first fillers or the second fillers contained in the joining layer, a sum of cross-sectional areas of the large-diameter fillers is larger than a sum of cross-sectional areas of the small-diameter fillers.

### Application Example 5

The retention device in accordance with any one of application examples 1 to 4, wherein
the retention device satisfies at least the condition (A), and
at least either the first fillers or the second fillers contained in the joining layer include the fillers having an aspect ratio of 1.4 or greater.

### Application Example 6

The retention device in accordance with any one of application examples 1 to 5, wherein
the retention device satisfies at least the condition (A), and
at least either the first fillers or the second fillers contained in the joining layer include the fillers having an aspect ratio of less than 1.4.

### Application Example 7

The retention device in accordance with any one of application examples 1 to 6, wherein
the retention device satisfies at least the condition (A), and
as for at least either the first fillers or the second fillers contained in the joining layer, a sum of cross-sectional areas of the fillers having an aspect ratio of 1.4 or greater is larger than a sum of cross-sectional areas of the fillers having an aspect ratio of less than 1.4.

### Application Example 8

The retention device in accordance with any one of application examples 1 to 7, wherein
the retention device satisfies at least the condition (A),
on at least either a portion of the retention member that is joined to the joining layer or a portion of the base member that is joined to the joining layer, recesses are formed so as to be recessed deeper than an average grain size of the fillers,
depths of the recesses are larger than the average grain size, and the recesses are filled with the joining layer, and
large-diameter fillers having a grain size larger than the average grain size of the fillers are in contact with surfaces defining the recesses.

### Application Example 9

The retention device in accordance with any one of application examples 1 to 8, wherein
the retention device satisfies at least the condition (A),
on at least either a portion of the retention member that is joined to the joining layer or a portion of the base member that is joined to the joining layer, recesses are formed so as to be recessed deeper than an average grain size of the fillers,
depths of the recesses are larger than the average grain size, and the recesses are filled with the joining layer, and
the fillers having an aspect ratio of 1.4 or greater are in contact with surfaces defining the recesses.

### Application Example 10

An electrostatic chuck including:
the retention device in accordance with any one of application examples 1 to 9; and
an electrostatic electrode configured to generate electrostatic attraction on the retention surface.

### DESCRIPTION OF REFERENCE NUMERALS

1: electrostatic chuck
10: retention member
10f: retention surface
12: electrostatic electrode
14: via
20, 20a: base member
20D: recess
20DS: surface
22: refrigerant flow path
30: joining layer
40: through hole
42: insulating member
44: metallization layer
46: connection terminal
48: metal terminal
F: filler
F1: first filler
F2: second filler
H, Ha: retention device

What is claimed is:

1. A retention device comprising:
a retention member having a retention surface for retaining a target object;
a base member placed on a side of the retention member opposite to the retention surface side; and
a joining layer joining the retention member and the base member and containing a plurality of fillers, wherein
the retention device satisfies at least one of the following conditions (A) to (C),
Condition (A): the fillers include at least either first fillers in contact with the retention member or second fillers in contact with the base member,
Condition (B): when a ratio of a sum of cross-sectional areas of the fillers in a first range of 1 μm or less from an interface of the joining layer with the retention member to a cross-sectional area of the first range is defined as a first ratio, a ratio of a sum of cross-sectional areas of the fillers in a second range of 1 μm or less from an interface of the joining layer with the base member to a cross-sectional area of the second range is defined as a second ratio, and a ratio of a sum of cross-sectional areas of the fillers in a third range of 30% or less of a thickness of the joining layer from a center of the joining layer in a thickness direction of the joining layer to the retention member side and a range of 30% or less of the thickness of the joining layer from the center to the base member side to a cross-sectional area of the third range is defined as a third ratio, at least one of a value obtained by dividing the first ratio by the third ratio and a value obtained by dividing the second ratio by the third ratio is 0.5 or greater, and
Condition (C): among the fillers, a number of the fillers having an aspect ratio of 1.4 or greater is larger than a number of the fillers having an aspect ratio of less than 1.4.

2. The retention device according to claim 1, wherein
the retention device satisfies at least the condition (A), and
at least either the first fillers or the second fillers contained in the joining layer include large-diameter fillers having a grain size larger than an average grain size of the fillers.

3. The retention device according to claim 2, wherein
the retention device satisfies at least the condition (A), and
at least either the first fillers or the second fillers contained in the joining layer include small-diameter fillers having a grain size smaller than the average grain size.

4. The retention device according to claim 3, wherein
the retention device satisfies at least the condition (A), and
as for at least either the first fillers or the second fillers contained in the joining layer, a sum of cross-sectional areas of the large-diameter fillers is larger than a sum of cross-sectional areas of the small-diameter fillers.

5. The retention device according to claim 1, wherein
the retention device satisfies at least the condition (A), and
at least either the first fillers or the second fillers contained in the joining layer include the fillers having an aspect ratio of 1.4 or greater.

6. The retention device according to claim 5, wherein
the retention device satisfies at least the condition (A), and
at least either the first fillers or the second fillers contained in the joining layer include the fillers having an aspect ratio of less than 1.4.

7. The retention device according to claim 6, wherein
the retention device satisfies at least the condition (A), and
as for at least either the first fillers or the second fillers contained in the joining layer, a sum of cross-sectional areas of the fillers having an aspect ratio of 1.4 or greater is larger than a sum of cross-sectional areas of the fillers having an aspect ratio of less than 1.4.

8. The retention device according to claim 1, wherein
the retention device satisfies at least the condition (A),
on at least either a portion of the retention member that is joined to the joining layer or a portion of the base member that is joined to the joining layer, recesses are formed so as to be recessed deeper than an average grain size of the fillers,
depths of the recesses are larger than the average grain size, and the recesses are filled with the joining layer, and
large-diameter fillers having a grain size larger than the average grain size of the fillers are in contact with surfaces defining the recesses.

9. The retention device according to claim 1, wherein
the retention device satisfies at least the condition (A),
on at least either a portion of the retention member that is joined to the joining layer or a portion of the base member that is joined to the joining layer, recesses are formed so as to be recessed deeper than an average grain size of the fillers,
depths of the recesses are larger than the average grain size, and the recesses are filled with the joining layer, and
the fillers having an aspect ratio of 1.4 or greater are in contact with surfaces defining the recesses.

10. An electrostatic chuck comprising:
the retention device according to claim 1; and
an electrostatic electrode configured to generate electrostatic attraction on the retention surface.
